(19) United States
(12) Patent Application Publication
(10) Pub. No.: US 2024/0381748 A1
(43) Pub. Date: Nov. 14, 2024

(54) DISPLAY PANEL AND DISPLAY DEVICE

(71) Applicant: Hubei Yangtze Industrial Innovation Center Of Advanced Display Co., Ltd., Wuhan (CN)

(72) Inventor: Yu CAI, Wuhan (CN)

(21) Appl. No.: 18/777,585

(22) Filed: Jul. 19, 2024

(30) Foreign Application Priority Data
Mar. 15, 2024 (CN) 202410299825.1

(51) Int. Cl. H10K 59/80

(52) U.S. Cl. CPC H10K 59/8791; H10K 59/873

(57) ABSTRACT

Provided are a display panel and a display device, including a light-emitting device layer, an anti-reflection layer and an encapsulation layer. The encapsulation layer is located at a side of the light-emitting device layer facing a light-exiting surface of the display panel. The anti-reflection layer is located between the light-emitting device layer and the encapsulation layer and configured to reduce reflection of ambient light by the display panel. The anti-reflection layer includes a metal layer including a first sub-metal layer and a second sub-metal layer that are stacked, and a dielectric layer including a first sub-dielectric layer located between the first sub-metal layer and the second sub-metal layer. A refractive index of the dielectric layer is greater than 1.3. Reflected light in a certain wave band reflected from interfaces of the anti-reflection layer interferes to counteract, reducing transmission and reflection of external ambient light.

### CROSS-REFERENCE TO RELATED APPLICATIONS

The present application claims priority to Chinese Patent Application No. 202410299825.1, filed on Mar. 15, 2024, the content of which is incorporated herein by reference in its entirety.

### TECHNICAL FIELD

The present disclosure relates to the field of display technology, and in particular, to a display panel and a display device.

### BACKGROUND

With the increasing use of display devices, users have higher and higher requirements for the quality of display images. However, in the related art, reflection of external ambient light may affect the quality of the display image of the display device, thereby affecting the display effect. Therefore, a solution is urgently needed.

### SUMMARY

In view of this, the embodiments of the present disclosure provide a display panel and a display device, which can reduce an influence of reflection of external ambient light on the display image and improve the display effect.

In an aspect, an embodiment of the present disclosure provides a display panel, including a light-emitting device layer, an anti-reflection layer and an encapsulation layer. The encapsulation layer is located at a side of the light-emitting device layer facing a light-exiting surface of the display panel, the anti-reflection layer is located between the light-emitting device layer and the encapsulation layer, and the anti-reflection layer is configured to reduce reflection of ambient light by the display panel. The anti-reflection layer includes a metal layer and a dielectric layer, the metal layer includes a first sub-metal layer and a second sub-metal layer that are stacked, the dielectric layer includes a first sub-dielectric layer located between the first sub-metal layer and the second sub-metal layer; and a refractive index of the dielectric layer is greater than 1.3.

In another aspect, an embodiment of the present disclosure provides a display device, including a display panel. The display panel includes a light-emitting device layer, an anti-reflection layer and an encapsulation layer. The encapsulation layer is located at a side of the light-emitting device layer facing a light-exiting surface of the display panel, the anti-reflection layer is located between the light-emitting device layer and the encapsulation layer, and the anti-reflection layer is configured to reduce reflection of ambient light by the display panel. The anti-reflection layer includes a metal layer and a dielectric layer, the metal layer includes a first sub-metal layer and a second sub-metal layer that are stacked, the dielectric layer includes a first sub-dielectric layer located between the first sub-metal layer and the second sub-metal layer; and a refractive index of the dielectric layer is greater than 1.3.

In the embodiments of the present disclosure, the anti-reflection layer includes a first sub-metal layer, a first sub-dielectric layer, and a second sub-metal layer that are stacked, so that a plasmon effect can be formed at an interface between the first sub-metal layer and the first sub-dielectric layer, and a plasmon effect can be formed at an interface between the second sub-metal layer and the first sub-dielectric layer. When external ambient light enters the anti-reflection layer, the reflected light in a certain wave band reflected from the multiple interfaces of the anti-reflection layer can interfere to counteract, thereby reducing transmission and reflection of external ambient light, and thus reducing an influence of reflection of external ambient light on the display image and improving the display effect of the display panel.

In addition, the refractive index of the first sub-dielectric layer is greater than 1.3, so that resonant tunneling can be formed in the anti-reflection layer, thereby allowing light in a specific wave band to pass through the anti-reflection layer, and thus ensuring that light emitted from the light-emitting device layer can pass through the anti-reflection layer and normally emit out, thereby avoiding that the anti-reflection layer affects the display of the display panel.

### BRIEF DESCRIPTION OF DRAWINGS

In order to better illustrate technical solutions in embodiments of the present disclosure, the accompanying drawings used in the embodiments are briefly introduced as follows. It should be noted that the drawings described as follows are merely part of the embodiments of the present disclosure, and other drawings can also be acquired by those skilled in the art without paying creative efforts.

FIG. 1 is a schematic structural diagram of a display panel according to an embodiment of the present disclosure;

FIG. 2 is a schematic structural diagram of an anti-reflection layer according to an embodiment of the present disclosure;

FIG. 3 is a schematic structural diagram of another display panel according to an embodiment of the present disclosure;

FIG. 4 is a schematic structural diagram of a further display panel according to an embodiment of the disclosure;

FIG. 5 is a schematic structural diagram of a further display panel according to an embodiment of the present disclosure;

FIG. 6 is a schematic structural diagram of a further display panel according to an embodiment of the present disclosure;

FIG. 7 is a schematic structural diagram of a further display panel according to an embodiment of the present disclosure;

FIG. 8 is a schematic structural diagram of a further display panel according to an embodiment of the present disclosure;

FIG. 9 is a schematic structural diagram of a further display panel according to an embodiment of the present disclosure;

FIG. 10 is a schematic structural diagram of a further display panel according to an embodiment of the present disclosure;

FIG. 11 is a schematic structural diagram of a further display panel according to an embodiment of the present disclosure;

FIG. 12 is a schematic structural diagram of a further display panel according to an embodiment of the present disclosure;

FIG. 13 is a schematic structural diagram of a further display panel according to an embodiment of the present disclosure;

FIG. 14 is a schematic structural diagram of a further display panel according to an embodiment of the present disclosure;

FIG. 15 is a schematic structural diagram of a further display panel according to an embodiment of the present disclosure;

FIG. 16 is a schematic structural diagram of a further display panel according to an embodiment of the present disclosure;

FIG. 17 is a schematic structural diagram of a further display panel according to an embodiment of the present disclosure;

FIG. 18 is a schematic structural diagram of a further display panel according to an embodiment of the present disclosure;

FIG. 19 is a schematic structural diagram of a further display panel according to an embodiment of the present disclosure;

FIG. 20 is a schematic structural diagram of another anti-reflection layer according to an embodiment of the present disclosure;

FIG. 21 is a schematic plan view of a display panel according to an embodiment of the present disclosure;

FIG. 22 is a schematic cross-sectional view along NN′ shown in FIG. 21; and

FIG. 23 is a schematic diagram of a display device according to an embodiment of the present disclosure.

### DESCRIPTION OF EMBODIMENTS

For better illustrating technical solutions of the present disclosure, embodiments of the present disclosure will be described in detail as follows with reference to the accompanying drawings.

It should be noted that, the described embodiments are merely exemplary embodiments of the present disclosure, which shall not be interpreted as providing limitations to the present disclosure. All other embodiments obtained by those skilled in the art without creative efforts according to the embodiments of the present disclosure are within the scope of the present disclosure.

The terms used in the embodiments of the present disclosure are merely for the purpose of describing particular embodiments but not intended to limit the present disclosure. Unless otherwise noted in the context, the singular form expressions “a”, “an”, “the” and “said” used in the embodiments and appended claims of the present disclosure are also intended to represent plural form expressions thereof.

It should be understood that the term “and/or” used herein is merely an association relationship describing associated objects, indicating that there may be three relationships, for example, A and/or B may indicate that three cases, i.e., A existing individually, A and B existing simultaneously, B existing individually. In addition, the character “/” herein generally indicates that the related objects before and after the character form an “or” relationship.

The present disclosure provides solutions to the problems existing in the related art.

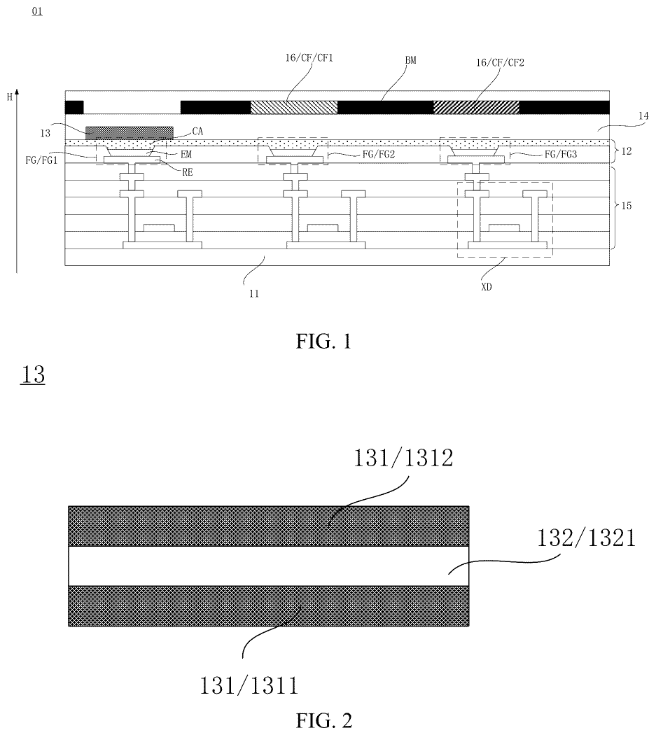

FIG. 1 is a schematic structural diagram of a display panel according to an embodiment of the present disclosure, and FIG. 2 is a schematic structural diagram of an anti-reflection layer according to an embodiment of the present disclosure.

An embodiment of the present disclosure provides a display panel 01, as shown in FIG. 1, the display panel 01 includes a substrate 11, a light-emitting device layer 12, an anti-reflection layer 13, and an encapsulation layer 14 that is located at a side of the light-emitting device layer 12 facing a light-exiting surface of the display panel 01 (that is, an encapsulation layer 14 that is located at a side of the light-emitting device layer 12 facing away from the substrate 11). The encapsulation layer 14 is configured to protect electronic elements arranged between the encapsulation layer 14 and the substrate 11. The anti-reflection layer 13 is located between the light-emitting device layer 12 and the encapsulation layer 14, and is configured to reduce reflection of external ambient light by the display panel 01.

As shown in FIG. 2, the anti-reflection layer 13 includes a metal layer 131 and a dielectric layer 132. The metal layer 131 can include at least one of silver, gold, copper, cobalt, nickel, ytterbium, bismuth, titanium, tungsten, and molybdenum. The dielectric layer 132 can be an organic layer or an inorganic layer.

The metal layer 131 includes a first sub-metal layer 1311 and a second sub-metal layer 1312. The dielectric layer 132 includes a first sub-dielectric layer 1321 located between the first sub-metal layer 1311 and the second sub-metal layer 1312. That is, in the anti-reflection layer 13, the first sub-metal layer 1311, the first sub-dielectric layer 1321, and the second sub-metal layer 1312 can be stacked. In an example, the first sub-dielectric layer 1321 is formed on the first sub-metal layer 1311 after the first sub-metal layer 1311 is formed, and the second sub-metal layer 1312 is formed on the first sub-dielectric layer 1321 after the first sub-dielectric layer 1321 is formed.

The refractive index of the dielectric layer 132 is greater than 1.3. The refractive index of the first sub-dielectric layer 1321 is greater than 1.3.

In the embodiments of the present disclosure, the anti-reflection layer 13 includes the first sub-metal layer 1311, the first sub-dielectric layer 1321, and the second sub-metal layer 1312 that are stacked. A plasmon effect can be formed at an interface between the first sub-metal layer 1311 and the first sub-dielectric layer 1321, and a plasmon effect can be formed at an interface between the second sub-metal layer 1312 and the first sub-dielectric layer 1321. When external ambient light enters the anti-reflection layer 13, the reflected light in a certain wave band reflected from the multiple interfaces of the anti-reflection layer 13 can interfere to counteract, thereby reducing transmission and reflection of the external ambient light. In this way, it can reduce an influence of reflection of the external ambient light on the display image, thereby improving the display effect of the display panel 01.

In addition, when the refractive index of the first sub-dielectric layer 1321 is greater than 1.3, resonant tunneling can be achieved in the anti-reflection layer 13, thereby allowing light in a certain wave band to pass through the anti-reflection layer 13, so that light emitted from the light-emitting device layer 12 can pass through the anti-reflection layer 13 to normally emit out, and thus avoiding the anti-reflection layer 13 from affecting the display image of the display panel 01.

The wave band of the light that can pass through the anti-reflection layer 13 can be changed by adjusting the refractive index of the first sub-dielectric layer 1321 within the range of the refractive index of the first sub-dielectric layer 1321. For example, the refractive index of the first sub-dielectric layer 1321 can be set to a certain value, so that red light can pass through the anti-reflection layer while green light and blue light cannot pass through the anti-reflection layer 13. Or, the refractive index of the first sub-dielectric layer 1321 can be set to another certain value, so that green light can pass through the anti-reflection layer 13 while red light and blue light cannot pass through the anti-reflection layer 13.

In addition, the wave band of the light that can pass through the anti-reflection layer 13 can be changed by adjusting the thickness of the first sub-dielectric layer 1321 in the anti-reflection layer 13. The wave band of light that can pass through the anti-reflection layer 13 can also be changed by simultaneously adjusting the refractive index and the thickness of the first sub-dielectric layer 1321 in the anti-reflection layer 13. The present disclosure can flexibly configure the anti-reflection layer 13 according to the light emitting requirements of the display panel 01.

Further referring to FIG. 1, in an embodiment of the present disclosure, the light-emitting device layer 12 includes a plurality of light-emitting devices FG, which can be organic light-emitting diodes. The light-emitting device FG includes a driving electrode RE, a light-emitting layer EM and a common electrode CA that are stacked. The light-emitting layer EM is located between the driving electrode RE and the common electrode CA, and the common electrode CA is located at a side of the driving electrode RE away from the substrate 11. The driving electrode RE can be an anode of the light-emitting device FG, and the common electrode CA can be a cathode of the light-emitting device FG.

The display panel 01 further includes a pixel circuit layer 15, which is located between the light-emitting device layer 12 and the substrate 11. The pixel circuit layer 15 includes a pixel circuit XD, which is electrically connected to the driving electrode RE of the light-emitting device FG and is configured to provide a light-emitting driving current for the light-emitting device FG.

The plurality of light-emitting devices FG include a first-color light-emitting device FG1, a second-color light-emitting device FG2, and a third-color light-emitting device FG3. The first-color light-emitting device FG1 emits first-color light, the second-color light-emitting device FG2 emits second-color light, and the third-color light-emitting device FG3 emits third-color light. The first-color light-emitting device FG1, the second-color light-emitting device FG2, and the third-color light-emitting device FG3 can respectively correspond to one of a red light-emitting device, a green light-emitting device, and a blue light-emitting device.

In the thickness direction H of the display panel 01, the anti-reflection layer 13 overlaps with at least one of the first-color light-emitting device FG1, the second-color light-emitting device FG2 and the third-color light-emitting device FG3. Further, the anti-reflection layer 13 is configured to transmit light emitted from the light-emitting device FG that overlaps with the anti-reflection layer 13.

That is, in the thickness direction H of the display panel 01, the anti-reflection layer 13 can overlap with any one of the first-color light-emitting device FG1, the second-color light-emitting device FG2, and the third-color light-emitting device FG3; or can overlap with any two of the first-color light-emitting device FG1, the second-color light-emitting device FG2, and the third-color light-emitting device FG3; or can overlap with all three of the first-color light-emitting device FG1, the second-color light-emitting device FG2, and the third-color light-emitting device FG3. The refractive index and/or the thickness of the dielectric layer 132 in the anti-reflection layer 13 can be adjusted, to make the anti-reflection layer 13 be capable of transmitting the light emitted from the light-emitting device FG that overlaps with the anti-reflection layer 13.

It should be noted that FIG. 1 merely illustrates that the anti-reflection layer 13 overlaps with the first-color light-emitting device FG1. In the structure of the display panel 01 shown in FIG. 1, the anti-reflection layer 13 is configured to transmit first-color light emitted from the first-color light-emitting device FG1.

In the embodiments of the present disclosure, the anti-reflection layers 13 can overlap with different light-emitting devices FG, thereby being beneficial to increasing the structure diversity of the display panel 01. While reducing the reflection influence of external ambient light, the structure of the anti-reflection layer 13 can be flexibly configured to meet different requirements of the display panel 01.

In an implementation of the embodiment of the present disclosure, referring to FIG. 1, in the thickness direction H of the display panel 01, the anti-reflection layer 13 overlaps with the first-color light-emitting device FG1 and is configured to transmit light emitted from the first-color light-emitting device FG1.

In an example, the anti-reflection layer 13 can be disposed on the first-color light-emitting device FG1. The anti-reflection layer 13 is formed on the common electrode CA of the first-color light-emitting device FG1 after the common electrode CA is formed. In this case, the anti-reflection layer 13 may not be arranged on the second-color light-emitting device FG2 and the third-color light-emitting device FG3.

Exemplarily, the first-color light-emitting device FG1 is a red light-emitting device. In this case, both the first sub-metal layer 1311 and the second sub-metal layer 1312 in the anti-reflection layer 13 can include silver. The refractive index of the first sub-dielectric layer 1321 is set to be greater than 1.3 and less than or equal to 1.4, and the thickness of the first sub-dielectric layer 1321 ranges from 163 nm to 178 nm. The anti-reflection layer 13 can allow transmission of red light, but does not allow transmission of green light and blue light. In an example, the thickness of the first sub-dielectric layer 1321 can be set to be 170 nm.

In addition, the thickness of the first sub-dielectric layer 1321 can be within a range from 102 nm to 114 nm, and the refractive index of the first sub-dielectric layer 1321 can be within a range from 1.7 to 2.0. Also, the anti-reflection layer 13 can allow transmission of red light, while does not allow transmission of green light and blue light. In an example, the thickness of the first sub-dielectric layer 1321 can be set to be 108 nm.

Exemplarily, the first-color light-emitting device FG1 is a green light-emitting device. In this case, both the first sub-metal layer 1311 and the second sub-metal layer 1312 in the anti-reflection layer 13 can include silver. The refractive index of the first sub-dielectric layer 1321 is set to be greater than 1.3 and less than or equal to 1.4, and the thickness of the first sub-dielectric layer 1321 ranges from 132 nm to 146 nm. The anti-reflection layer 13 can allow transmission of green light, but does not allow transmission of red light and blue light. In an example, the thickness of the first sub-dielectric layer 1321 can be set to be 139 nm.

In addition, the thickness of the first sub-dielectric layer 1321 can be within a range from 102 nm to 114 nm, and the refractive index of the first sub-dielectric layer 1321 can be within a range from 1.5 to 1.6. Also, the anti-reflection layer 13 can allow transmission of green light, while does not allow transmission of red light and blue light. In an example, the thickness of the first sub-dielectric layer 1321 can be set to be 108 nm.

Exemplarily, the first-color light-emitting device FG1 is a blue light-emitting device. In this case, both the first sub-metal layer 1311 and the second sub-metal layer 1312 in the anti-reflection layer 13 can include silver. The refractive index of the first sub-dielectric layer 1321 is set to be greater than 1.3 and less than or equal to 1.4, and the thickness of the first sub-dielectric layer 1321 ranges from 102 nm to 114 nm. The anti-reflection layer 13 can allow transmission of blue light, but does not allow transmission of red light and green light. In an example, the thickness of the first sub-dielectric layer 1321 can be set to be 108 nm.

In these embodiments of the present disclosure, the anti-reflection layer 13 is configured to transmit light emitted from the first-color light-emitting device FG1, so that the anti-reflection layer 13 can reduce transmission and reflection of external ambient light through the anti-reflection layer 13 without affecting light emission of the first-color light, thereby being beneficial to reducing the influence of external ambient light on the quality of the display image.

As shown in FIG. 1, in an embodiment of the present disclosure, the display panel 01 further includes a color resist layer 16. The color resist layer 16 is located at a side of the light-emitting device layer 12 facing the light-exiting surface of the display panel, and can be disposed at a side of the encapsulation layer 14 away from the substrate 11.

The color resist layer 16 includes a plurality of color resists CF, which include a second-color resist CF1 and a third-color resist CF2. A black matrix BM is arranged between the second-color resist CF1 and the third-color resist CF2, and the black matrix BM can block external ambient light. A black matrix BM can be disposed between two adjacent color resists CF. In the thickness direction H of the display panel 01, the second-color resist CF1 overlaps with the second-color light-emitting device FG2, and the third-color resist CF2 overlaps with the third-color light-emitting device FG3. The second-color resist CF1 can cover the second-color light-emitting device FG2, and the third-color resist CF2 can cover the third-color light-emitting device FG3.

When the first color is red, the second color and the third color be can green and blue, respectively; when the first color is green, the second color and the third color can be red and blue, respectively; when the first color is blue, the second color and the third color can be red and green, respectively.

It can be known from the characteristics of the color resist CF that the color resist CF allows light having the same color as the color resist CF to pass through and block light having a different color. In the embodiments of the present disclosure, the second-color resist CF1 can allow the second-color light to pass through and block light having other colors, thereby reducing incidence and reflection of external ambient light through the second-color resist CF1 while not affecting light emission of the second-color light. The third-color resist CF2 can allow the third-color light to pass through and block light with other colors, thereby reducing incidence and reflection of external ambient light through the third-color resist CF2 while not affecting light emission of the third-color light. In the embodiments of the present disclosure, the second-color resist CF1, the third-color resist CF2 and the anti-reflection layer 13 that is located at the side of the first-color light-emitting device FG1 away from the substrate 11 cooperate with each other, thereby further reducing transmission and reflection of external ambient light while ensuring that light emitted from the light-emitting device layer 12 can be normally emitted out, thereby improving the display quality of the display panel 01.

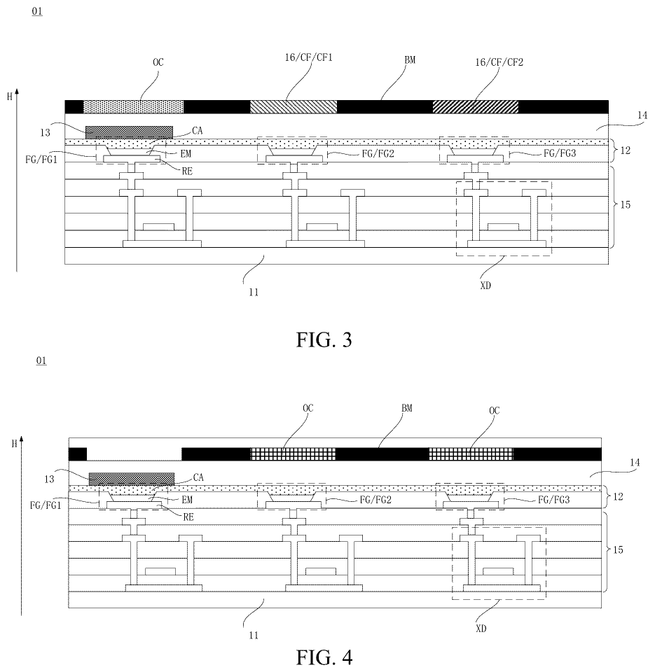

FIG. 3 is a schematic structural diagram of another display panel according to an embodiment of the present disclosure.

Further, as shown in FIG. 3, a reflection control layer OC is further provided at a side of the anti-reflection layer 11 away from the first-color light-emitting device FG1, and overlaps with the first-color light-emitting device FG1 in the thickness direction H of the display panel 01. In this case, the reflection control layer OC can be configured to transmit first-color light emitted from the first-color light-emitting device FG. While ensuring the light emission effect of the first-color light-emitting device FG, the light transmittance of the reflection control layer OC can be set to be relatively small, thereby reducing transmission and reflection of external ambient light.

The reflection control layer OC can be located at a side of the encapsulation layer 14 away from the substrate 11. The reflection control layer OC and the color resist layer CF can be in contact with a same film layer in the thickness direction H of the display panel 01. A black matrix BM is arranged between the reflection control layer OC and the color resist CF, to prevent external ambient light from entering the interior of the display panel 01 through a region between the reflection control layer OC and the color resist CF, thereby further reducing transmission and reflection of external ambient light.

FIG. 4 is a schematic structural diagram of a further display panel according to the embodiment of the disclosure.

In an embodiment of the present disclosure, as shown in FIG. 4, the display panel 01 further includes a reflection control layer OC. The reflection control layer OC is located at a side of the light-emitting device layer 12 facing the light-exiting surface of the display panel 01, and can be disposed at a side of the encapsulation layer 14 away from the substrate 11.

In the thickness direction H of the display panel 01, the reflection control layer OC overlaps with the second-color light-emitting device FG2 and the third-color light-emitting device FG3, and is configured to transmit light emitted from the second-color light-emitting device FG2 and the third-color light-emitting device FG3. That is, the reflection control layer OC allows the second-color light emitted by the second-color light-emitting device FG2 to pass through, and allows the third-color light emitted by the third-color light-emitting device FG3 to pass through. In this case, the reflection control layer OC may not allow light having a color other than the second color and the third color to pass through.

Exemplarily, when the first color is red, the second color and the third color can be green and blue, respectively. In this case, the reflection control layer OC can be configured to allow green light and blue light to pass through. When the first color is green, the second color and the third color can be red and blue, respectively. In this case, the reflection control layer OC can be configured to allow red light and blue light to pass through. When the first color is blue, the second color and the third color can be red and green, respectively. In this case, the reflection control layer OC can be configured to allow red light and green light to pass through.

The reflection control layer OC can be an organic layer including materials such as dyes and pigments. The reflection control layer OC can transmit or block light having different colors by setting different material characteristics of the material included in the reflection control layer OC.

In the embodiments of the present disclosure, the reflection control layer OC can transmit the second-color light emitted by the second-color light-emitting device FG2 and the third-color light emitted by the third-color light-emitting device FG3, and can block light having other colors, thereby reducing transmission and reflection of external ambient light through the reflection control layer OC while not affecting light emission of the second-color light and the third-color light. In the embodiments of the present disclosure, the reflection control layer OC can cooperate with the anti-reflection layer 13 located at a side of the first-color light-emitting device FG1 away from the substrate 11, to further reduce transmission and reflection of external ambient light while ensuring that the light emitted by the light-emitting device layer 12 can be normally emitted out, thereby improving the display quality of the display panel 01.

Moreover, in the manufacture process of the display panel 01, compared with a case shown in FIG. 3 that the second-color resist CF1 and the third-color resist CF2 need to be formed separately, the reflection control layer OC in this embodiment can be formed integrally, thereby being beneficial to simplifying the manufacture process of the display panel 01.

It should be noted that, in the display panel 01, a black matrix BM is arranged between the regions where the first-color light-emitting device FG1, the second-color light-emitting device FG2 and the third-color light-emitting device FG3 are located, thereby further preventing external ambient light from entering the interior of the display panel 01 while not affecting the emission of light emitted by the light-emitting device layer 12, and thus reducing an influence of reflection of external ambient light on the image quality of the display panel 01.

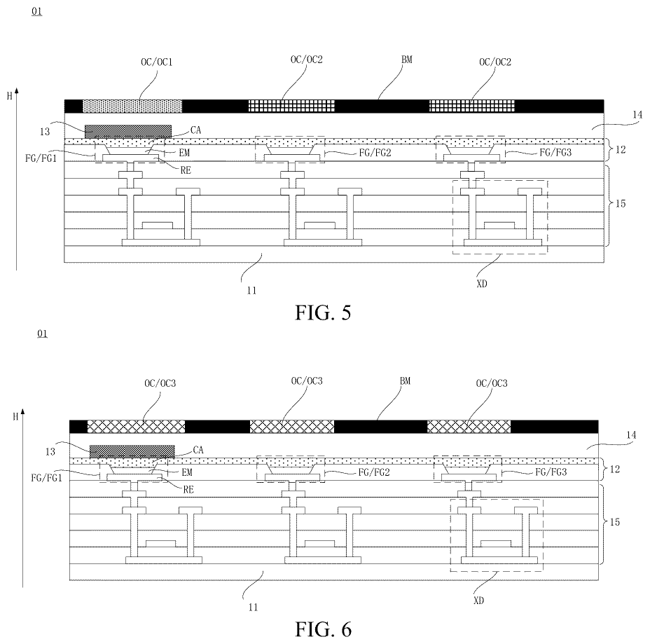

FIG. 5 is a schematic structural diagram of a further display panel according to an embodiment of the present disclosure.

Further, as shown in FIG. 5, a reflection control layer OC transmitting the first-color light is further provided at a side of the anti-reflection layer 13 away from the first-color light-emitting device FG1. In the thickness direction H of the display panel 01, the reflection control layer OC overlaps with the first-color light-emitting device FG1, and does not allow the second-color light and the third-color light to pass through. While ensuring the light emission effect of the first-color light-emitting device FG, the light transmittance of the reflection control layer OC can be set to be relatively small, thereby reducing transmission and reflection of external ambient light.

In this case, in the display panel 01, the reflection control layer OC overlapping with the first-color light-emitting device FG1 is configured to transmit the first-color light, and the reflection control layer OC overlapping with the second-color light-emitting device FG2 and the third-color light-emitting device FG3 is configured to transmit the second-color light and the third-color light. For clarity of illustration, as shown in FIG. 5, the reflection control layer OC transmitting the first-color light is labeled as OC1, and the reflection control layer OC transmitting the second and the third-color light is labeled as OC2.

FIG. 6 is a schematic structural diagram of a further display panel according to an embodiment of the present disclosure.

In an embodiment of the present disclosure, as shown in FIG. 6, the reflective transmission layer OC is located at a side of the encapsulation layer 14 away from the substrate 11. In the thickness direction H of the display panel 01, the reflective transmission layer OC overlaps with each of the first-color light-emitting device FG1, the second-color light-emitting device FG2 and the third-color light-emitting device FG3. The reflective transmission layer OC is configured to transmit light emitted by the first-color light-emitting device FG1, light emitted by the second-color light-emitting device FG2 and light emitted by the third-color light-emitting device FG3. To distinguish from the reflective transmission layer OC in FIG. 5, the reflective transmission layer OC transmitting the first-color light, the second-color light, and the third-color light simultaneously is labeled as OC3, as shown in FIG. 6.

In the embodiments of the present disclosure, compared with a case shown in FIG. 5 that the reflection control layer OC1 and the reflection control layer OC2 need to be formed separately, the reflective transmission layer OC3 in this embodiment can be formed integrally, thereby being beneficial to simplifying the manufacture process of the display panel 01.

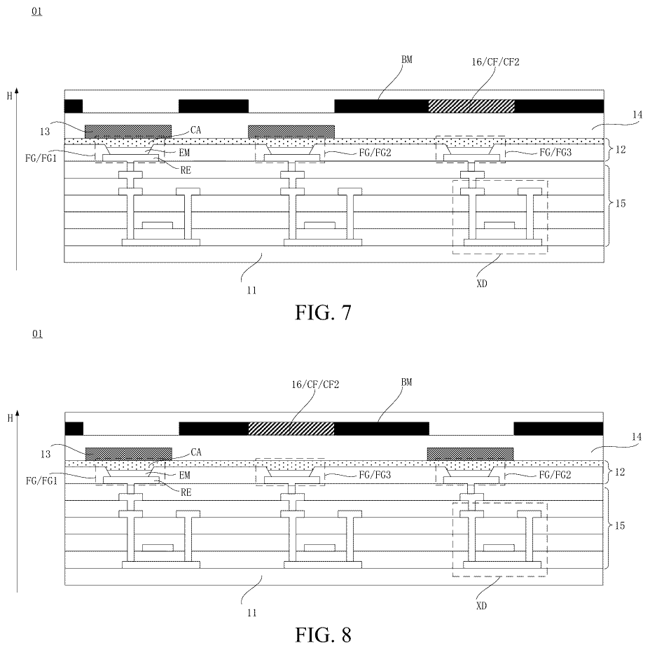

FIG. 7 is a schematic structural diagram of a further display panel according to an embodiment of the present disclosure, and FIG. 8 is a schematic structural diagram of a further display panel according to an embodiment of the present disclosure.

In an embodiment of the present disclosure, as shown in FIG. 7 and FIG. 8, in the thickness direction H of the display panel 01, the anti-reflection layer 13 overlaps with the first-color light-emitting device FG1 and the second-color light-emitting device FG2. The anti-reflection layer 13 is configured to transmit light emitted by the first-color light-emitting device FG1 and light emitted by the second-color light-emitting device FG2. The first-color light-emitting device FG1 and the second-color light-emitting device FG2 can be any two of a red light-emitting device, a green light-emitting device, and a blue light-emitting device.

As shown in FIG. 7, the first-color light-emitting device FG1 may be adjacent to the second-color light-emitting device FG2. As shown in FIG. 8, the first-color light-emitting device FG1 may not be adjacent to the second-color light-emitting device FG2.

In an example, the anti-reflection layer 13 can be arranged on the first-color light-emitting device FG1 and the second-color light-emitting device FG2. After the common electrode CA is formed, the anti-reflection layer 13 is formed on the common electrode CA of the first-color light-emitting device FG1 and the second-color light-emitting device FG2. In this case, the anti-reflection layer 13 can be not arranged on the third-color light-emitting device FG3.

Exemplarily, the first-color light-emitting device FG1 is a red light-emitting device, and the second-color light-emitting device FG2 is a blue light-emitting device. In this case, both the first sub-metal layer 1311 and the second sub-metal layer 1312 in the anti-reflection layer 13 can include silver. The refractive index of the first sub-dielectric layer 1321 is set to be greater than 1.3 and less than or equal to 1.4, and the thickness of the first sub-dielectric layer 1321 ranges from 374 nm to 414 nm. The anti-reflection layer 13 allows transmission of red light and blue light, but does not allow transmission of green light. In an example, the thickness of the first sub-dielectric layer 1321 can be set to be 394 nm.

Exemplarily, the first-color light-emitting device FG1 is a green light-emitting device, and the second-color light-emitting device FG2 is a blue light-emitting device. In this case, both the first sub-metal layer 1311 and the second sub-metal layer 1312 in the anti-reflection layer 13 can include silver. The refractive index of the first sub-dielectric layer 1321 is set to be greater than 1.3 and less than or equal to 1.4, and the thickness of the first sub-dielectric layer 1321 ranges from 502 nm to 556 nm. The anti-reflection layer 13 allows transmission of green light and blue light, but does not allow transmission of red light. In an example, the thickness of the first sub-dielectric layer 1321 can be set to be 529 nm.

In the embodiments of the present disclosure, the anti-reflection layer 13 is configured to transmit light emitted by the first-color light-emitting device FG1 and light emitted by the second-color light-emitting device FG2, thereby reducing transmission and reflection of external ambient light through the anti-reflection layer 13 while not affecting light emission of the first-color light and the second-color light, and thus reducing an influence of reflection of external ambient light on the quality of the display image.

Still referring to FIG. 7 and FIG. 8, in an embodiment of the present disclosure, the display panel 01 further includes a color resist layer 16. The color resist layer 16 is located at a side of the light-emitting device layer 12 facing the light-exiting surface of the display panel, and can be disposed at a side of the encapsulation layer 14 away from the substrate 11.

The color resist layer 16 includes a plurality of color resists CF, which include a third-color resist CF2 overlapping with the third-color light-emitting device FG3 in the thickness direction H of the display panel 01. The third-color resist CF2 can cover the third-color light-emitting device FG3.

The third color can be any one of red, green, and blue, and is different from the first color and the second color.

It can be known from the characteristics of the color resist CF that the color resist CF allows light having the same color as the color resist CF to pass through and block light having a different color. In the embodiments of the present disclosure, the third-color resist CF2 allows the third-color light to pass through and block light having other colors, thereby reducing incidence and reflection of external ambient light through the third-color resist CF2 while not affecting light emission of the third-color light. In the embodiments of the present disclosure, the third-color resist CF2 cooperates with the anti-reflection layer 13, thereby further reducing transmission and reflection of external ambient light while ensuring that the light emitted by the light-emitting device layer 12 can be normally emitted out, and thus improving the display quality of the display panel 01.

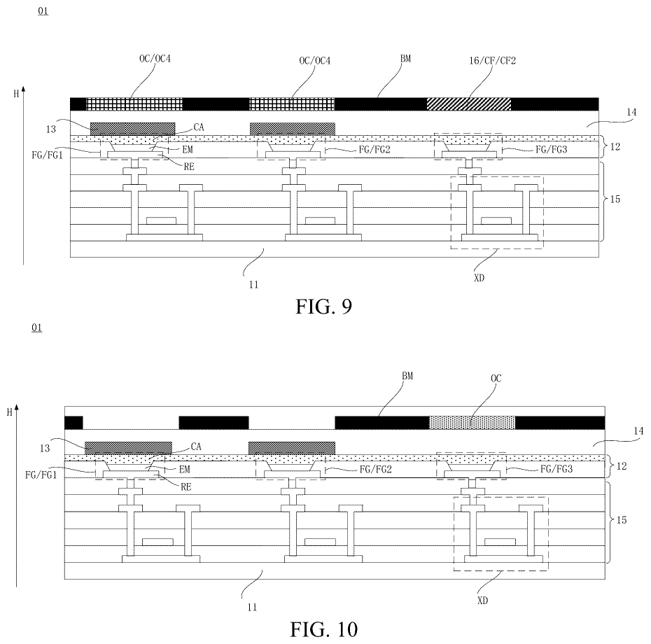

FIG. 9 is a schematic structural diagram of a further display panel according to an embodiment of the present disclosure.

Further, as shown in FIG. 9, a reflection control layer OC is further provided at a side of the anti-reflection layer 13 away from the substrate 11, and can be located at a side of the encapsulation layer 14 away from the substrate 11. The reflection control layer OC and the color resist layer CF can be in contact with a same film layer in the thickness direction H of the display panel 01.

In the thickness direction H of the display panel 01, the reflection control layer OC overlaps with each of the first-color light-emitting device FG1 and the second-color light-emitting device FG2. In this case, the reflection control layer OC can be configured to transmit the first-color light emitted by the first-color light-emitting device FG1 and the second-color light emitted by the second-color light-emitting device FG2. While ensuring the light emission effect of the first-color light-emitting device FG1 and the second-color light-emitting device FG2, the light transmittance of the reflection control layer OC can be set to be relatively small, thereby reducing transmission and reflection of external ambient light.

A black matrix BM is provided between the reflection control layer OC and the color resist CF, and a black matrix BM is provided between portions of the reflection control layers OC overlapping with light-emitting devices FG having different colors. In this way, it is beneficial for the black matrix BM to be arranged between the regions where the first-color light-emitting device FG1, the second-color light-emitting device FG2 and the third-color light-emitting device FG3 are located, and it can prevent external ambient light from entering the interior of the display panel 01 while not affecting light emission of light emitted by the light-emitting device layer 12, thereby reducing an influence of reflection of external ambient light on the image quality of the display panel 01.

FIG. 10 is a schematic structural diagram of a further display panel according to an embodiment of the present disclosure.

In an embodiment of the present disclosure, as shown in FIG. 10, the display panel 01 further includes a reflection control layer OC. The reflection control layer OC is located at a side of the light-emitting device layer 12 facing the light-exiting surface of the display panel 01, and can be disposed at a side of the encapsulation layer 14 away from the substrate 11.

In the thickness direction H of the display panel 01, the reflection control layer OC overlaps with the third-color light-emitting device FG3, and is configured to transmit light emitted by the third-color light-emitting device FG3. That is, the reflection control layer OC allows the third-color light emitted by the third-color light-emitting device FG2 to pass through. In this case, the reflection control layer OC may not allow light having a color other than the third color to pass through.

Exemplarily, when the first color and the second color are red and green, respectively, the third color can be blue. In this case, the reflection control layer OC can be configured to allow the blue light to pass through. When the first color and the second color are red and blue, respectively, the third color can be green. In this case, the reflection control layer OC can be configured to allow the green light to pass through. When the first color and the second color are blue and green, respectively, the third color can be red. In this case, the reflection control layer OC can be configured to allow the red light to pass through.

The reflection control layer OC can be an organic layer including materials such as dyes and pigments. The reflection control layer OC can transmit or block light having different colors by setting different material characteristics of the material included in the reflection control layer OC.

In this embodiment of the present disclosure, the reflection control layer OC may transmit the third-color light emitted by the third-color light-emitting device FG3, and block light having other colors, thereby reducing transmission and reflection of external ambient light through the reflection control layer OC while not affecting light emission of the third-color light. In the embodiments of the present disclosure, the reflection control layer OC cooperates with the anti-reflection layer 13, thereby further reducing transmission and reflection of external ambient light while ensuring that the light emitted by the light-emitting device layer 12 can be normally emitted out, and thus improving the display quality of the display panel 01.

It should be noted that in the display panel 01, a black matrix BM is provided between regions where the first-color light-emitting device FG1, the second-color light-emitting device FG2 and the third-color light-emitting device FG3 are located. The black matrix BM and the reflection control layer OC can be in contact with a same film layer in the thickness direction H of the display panel 01. It can further prevent external ambient light from entering the interior of the display panel 01 while not affecting light emission of light emitted by the light-emitting device layer 12, thereby reducing an influence of reflection of external ambient light on the image quality of the display panel 01.

FIG. 11 is a schematic structural diagram of a further display panel according to an embodiment of the present disclosure.

Further, as shown in FIG. 11, a reflection control layer OC transmitting the first-color light and the second-color light can also be provided at a side of the anti-reflection layer 13 away from the first-color light-emitting device FG1 and the second-color light-emitting device FG2. In the thickness direction H of the display panel 01, the reflection control layer OC overlaps with each of the first-color light-emitting device FG1 and the second-color light-emitting device FG2, and may not allow the third-color light to pass through. While ensuring the light emission effect of the first-color light-emitting device FG1 and the second-color light-emitting device FG2, the light transmittance of the reflection control layer OC can be set to be relatively small, thereby reducing transmission and reflection of external ambient light.

In this case, in the display panel 01, the reflection control layer OC overlapping with each of the first-color light-emitting device FG1 and the second-color light-emitting device FG2 is configured to transmit the first-color light and the second-color light; and the reflection control layer OC overlapping with the third-color light-emitting device FG3 is configured to transmit the third-color light. For clarity of illustration, as shown in FIG. 11, the reflection control layer OC transmitting the first-color light and the second-color light is labeled as OC4, and the reflection control layer OC transmitting the third-color light is labeled as OC5.

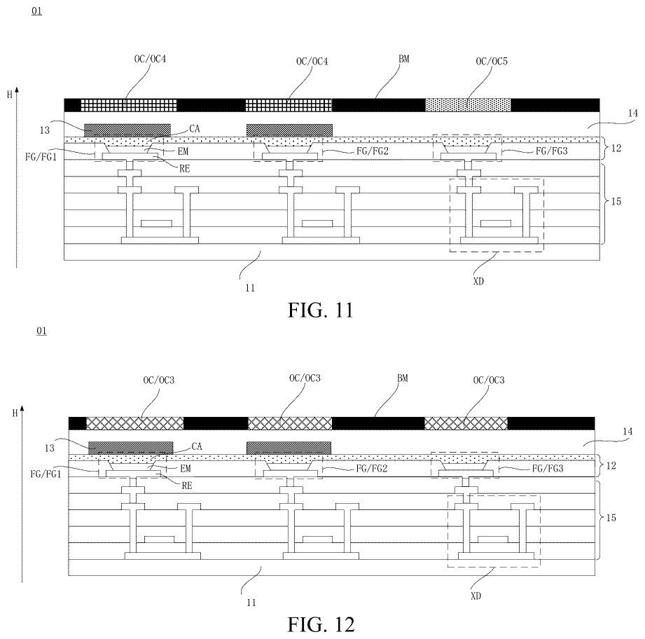

FIG. 12 is a schematic structural diagram of a further display panel according to an embodiment of the present disclosure.

In an embodiment of the present disclosure, the reflective transmission layer OC can be further configured to transmit light emitted by the first-color light-emitting device FG1, the second-color light-emitting device FG2, and the third-color light-emitting device FG3. As shown in FIG. 12, the reflective transmission layer OC is located at a side of the encapsulation layer 14 away from the substrate 11. In the thickness direction H of the display panel 01, the reflective transmission layer OC overlaps with each of the first-color light-emitting device FG1, the second-color light-emitting device FG2 and the third-color light-emitting device FG3. To distinguish from the reflective transmission layer OC in FIG. 11, the reflective transmission layer OC transmitting each of the first-color light, the second-color light, and the third-color light simultaneously is labeled as OC3, as shown in FIG. 12.

In the embodiments of the present disclosure, compared with a case shown in FIG. 11 that the reflection control layer OC4 and the reflection control layer OC5 need to be formed separately, the reflective transmission layer OC3 in this embodiment can be formed integrally, thereby being beneficial to simplifying the manufacture process of the display panel 01.

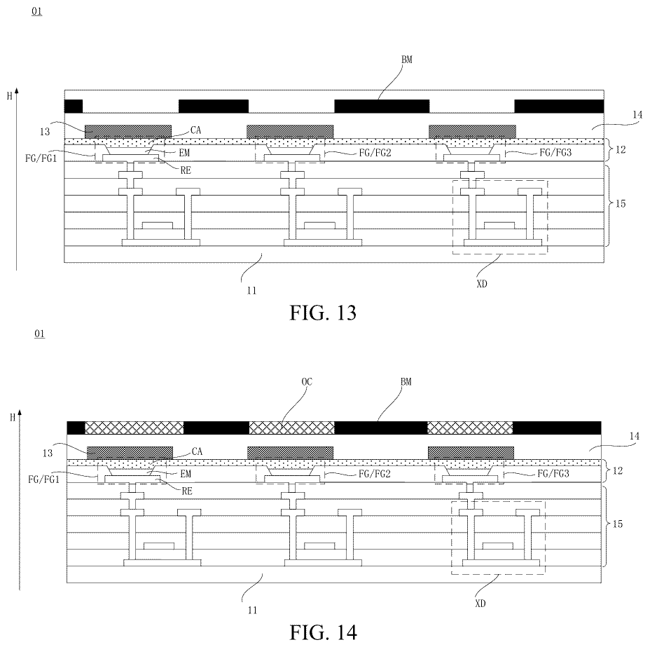

FIG. 13 is a schematic structural diagram of a further display panel according to an embodiment of the present disclosure.

In an embodiment of the present disclosure, as shown in FIG. 13, in the thickness direction H of the display panel 01, the anti-reflection layer 13 overlaps with each of the first-color light-emitting device FG1, the second-color light-emitting device FG2 and the third-color light-emitting device FG3. The anti-reflection layer 13 is configured to transmit light emitted by the first-color light-emitting device FG1, the second-color light-emitting device FG2 and the third-color light-emitting device FG3. That is, each of the first-color light, the second-color light, and the third-color light can pass through the anti-reflection layer 13.

The first-color light-emitting device FG1, the second-color light-emitting device FG2, and the third-color light-emitting device FG3 can be a red light-emitting device, a green light-emitting device, and a blue light-emitting device, respectively.

In an example, the anti-reflection layer 13 can be provided on the first-color light-emitting device FG1, the second-color light-emitting device FG2, and the third-color light-emitting device FG3. After the common electrode CA is formed, the anti-reflection layer 13 is formed on the common electrodes CA of each of the first-color light-emitting device FG1, the second-color light-emitting device FG2 and the third-color light-emitting device FG3.

Exemplarily, both the first sub-metal layer 1311 and the second sub-metal layer 1312 in the anti-reflection layer 13 can include silver. The refractive index of the first sub-dielectric layer 1321 is set to be greater than 1.3 and less than or equal to 1.6, and the thickness of the first sub-dielectric layer 1321 ranges from 587 nm to 649 nm. The anti-reflection layer 13 allows transmission of green light, blue light and red light. In an example, the refractive index of the first sub-dielectric layer 1321 of the first sub-dielectric layer 1321 can be set to be 1.4 or 1.5, and the thickness can be set to be 618 nm.

In the embodiments of the present disclosure, the anti-reflection layer 13 is provided on each of the first-color light-emitting device FG1, the second-color light-emitting device FG2, and the third-color light-emitting device FG3, thereby reducing transmission and reflection of external ambient light through the anti-reflection layer 13 while ensuring that the light of the light-emitting device layer 12 can be normally emitted out, and thus further reducing an influence of reflection of external ambient light on display quality of the display image.

In addition, the anti-reflection layer 13 can transmit light emitted by the first-color light-emitting device FG1, the second-color light-emitting device FG2 and the third-color light-emitting device FG3, so that the anti-reflection layer 13 on the first-color light-emitting device FG1, the second-color light-emitting device FG2 and the third-color light-emitting device FG3 can be integrally formed, thereby being beneficial to simplifying the process and saving the manufacturing cost of the display panel 01.

FIG. 14 is a schematic structural diagram of a further display panel according to an embodiment of the present disclosure.

Further, as shown in FIG. 14, the display panel 01 further includes a reflection control layer OC. The reflection control layer OC is located at a side of the light-emitting device layer 12 facing the light-exiting surface of the display panel 01. The reflection control layer OC can be arranged at a side of the encapsulation layer 14 away from the substrate 11. The light transmittance of the reflection control layer OC may range from 40% to 70%.

In the thickness direction H of the display panel 01, the reflection control layer OC overlaps with each of the first-color light-emitting device FG1, the second-color light-emitting device FG2 and the third-color light-emitting device FG3.

In an example, the reflection control layer OC does not transmit light selectively.

In an example, the reflection control layer OC transmits light selectively. In this case, the reflection control layer 13 can be configured to transmit each of the first-color light, the second-color light, and the third-color light; or a portion of the reflection control layer 13 overlapping with the first-color light-emitting device FG1 is configured to transmit the first-color light, a portion of the reflection control layer 13 overlapping with the second-color light-emitting device FG2 is configured to transmit the second-color light, and a portion of the reflection control layer 13 overlapping with the third-color light-emitting device FG3 is configured to transmit the third-color light.

In this way, the anti-reflection layer 13 can cooperate with the reflection control layer OC having lower light transmittance, thereby being beneficial to further reducing incidence and reflection of external ambient light, and thus improving the display effect of the display panel 01.

It should be noted that in the display panel 01, a black matrix BM is provided between regions where the first-color light-emitting device FG1, the second-color light-emitting device FG2 and the third-color light-emitting device FG3 are located, and the black matrix BM and the reflection control layer OC can be in contact with a same film layer in the thickness direction H of the display panel 01. It can prevent external ambient light from entering the interior of the display panel 01 while not affecting light emission of the light emitted by the light-emitting device layer 12, thereby reducing an influence of reflection of external ambient light on the image quality of the display panel 01.

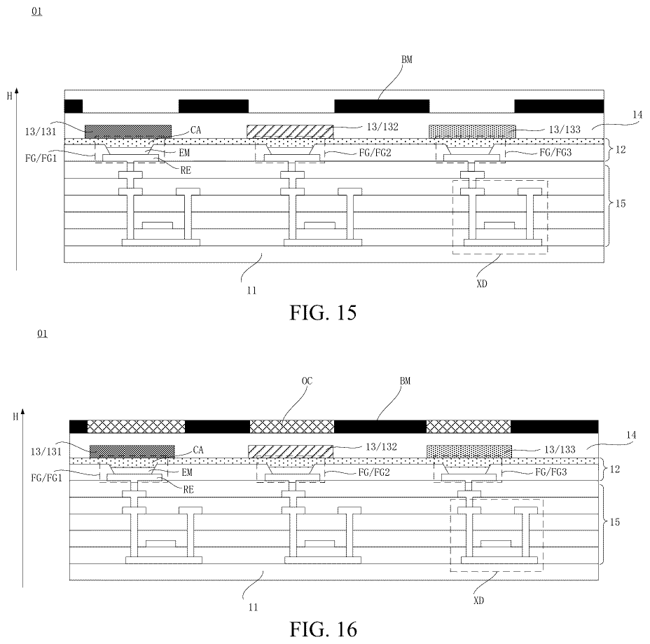

FIG. 15 is a schematic structural diagram of a further display panel according to an embodiment of the present disclosure.

In an embodiment of the present disclosure, as shown in FIG. 15, the anti-reflection layer 13 includes a first-type anti-reflection layer 131, a second-type anti-reflection layer 132, and a third-type anti-reflection layer 133. In the thickness direction H of the display panel 01, the first-type anti-reflection layer 131 overlaps with the first-color light-emitting device FG1, the second-type anti-reflection layer 132 overlaps with the second-color light-emitting device FG2, and the third-type anti-reflection layer 133 overlaps with the third-color light-emitting device FG3.

The first-type anti-reflection layer 131 is configured to transmit light emitted by the first-color light-emitting device FG1, the second-type anti-reflection layer 132 is configured to transmit light emitted by the second-color light-emitting device FG2, and the third-type anti-reflection layer 133 is configured to transmit light emitted by the third-color light-emitting device FG3.

In an example, after the common electrode CA is formed, the first-type anti-reflection layer 131 is formed on the first-color light-emitting device FG1, the second-type anti-reflection layer 132 is formed on the second-color light-emitting device FG2, and the third-type anti-reflection layer 133 is formed on the third-color light-emitting device FG3.

In an embodiment of the present disclosure, the anti-reflection layer 13 is provided on each of the first-color light-emitting device FG1, the second-color light-emitting device FG2, and the third-color light-emitting device FG3, thereby reducing transmission and reflection of external ambient light through the anti-reflection layer 13 while ensuring that the light of the light-emitting device layer 12 can be normally emitted out, and thus further reducing an influence of reflection of external ambient light on display quality of the display image.

Moreover, by configuring the anti-reflection layers overlapping with the light-emitting devices FG having different colors to be different types, it is beneficial to making the first-type anti-reflection layer 131, the second-type anti-reflection layer 132 and the third-type anti-reflection layer 133 have more selective implementations. On the one hand, it is beneficial to reducing the implementation difficulty of the first-type anti-reflection layer 131, the second-type anti-reflection layer 132 and the third-type anti-reflection layer 133; and on the other hand, it is beneficial to increasing the structural diversity of the display panel 01.

FIG. 16 is a schematic structural diagram of a further display panel according to an embodiment of the present disclosure.

Further, as shown in FIG. 16, the display panel 01 further includes a reflection control layer OC. The reflection control layer OC is located at a side of the light-emitting device layer 12 facing the light-exiting surface of the display panel 01, and can be disposed at a side of the encapsulation layer 14 away from the substrate 11. The light transmittance of the reflection control layer OC ranges from 40% to 70%.

In the thickness direction H of the display panel 01, the reflection control layer OC overlaps with each of the first-color light-emitting device FG1, the second-color light-emitting device FG2 and the third-color light-emitting device FG3.

In an example, the reflection control layer OC is a film layer that does not transmit light selectively.

In an example, the reflection control layer OC transmits light selectively. In this case, the reflection control layer 13 can be configured to transmit the first-color light, the second-color light, and the third-color light simultaneously; or a portion of the reflection control layer 13 overlapping with the first-color light-emitting device FG1 is configured to transmit the first-color light, a portion of the reflection control layer 13 overlapping with the second-color light-emitting device FG2 is configured to transmit the second-color light, and a portion of the reflection control layer 13 overlapping with the third-color light-emitting device FG3 is configured to transmit the third-color light.

In this way, the anti-reflection layer 13 can cooperate with the reflection control layer OC having lower light transmittance, thereby being is beneficial to further reducing incidence and reflection of external ambient light, and thus further improving the display effect of the display panel 01.

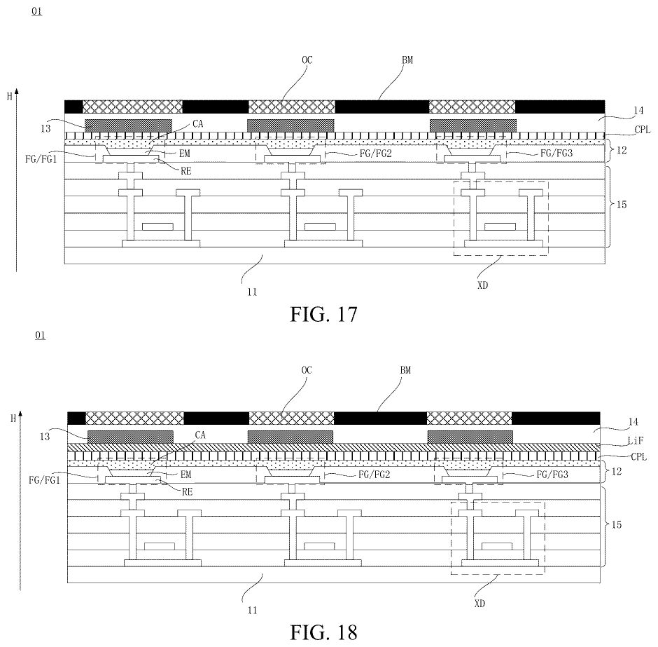

FIG. 17 is a schematic structural diagram of a further display panel according to an embodiment of the present disclosure, and FIG. 18 is a schematic structural diagram of a further display panel according to an embodiment of the present disclosure.

In an embodiment of the present disclosure, as shown in FIG. 17, the display panel 01 further includes a cap layer CPL disposed on the common electrode CA. That is, the cap layer CPL is formed after the common electrode CA is formed. The cap layer CPL can be used to improve the light emission efficiency of the light-emitting device FG. In this case, the anti-reflection layer 13 can be disposed on the cap layer CPL.

Further, the display panel 01 can further include a lithium fluoride layer LiF disposed on the cap layer CPL, as shown in FIG. 18. That is, a lithium fluoride layer LiF is formed after the cap layer CPL is formed. The lithium fluoride layer LiF can also be used to improve the light emission efficiency of the light-emitting device FG. In this case, the anti-reflection layer 13 can be disposed on the lithium fluoride layer LiF.

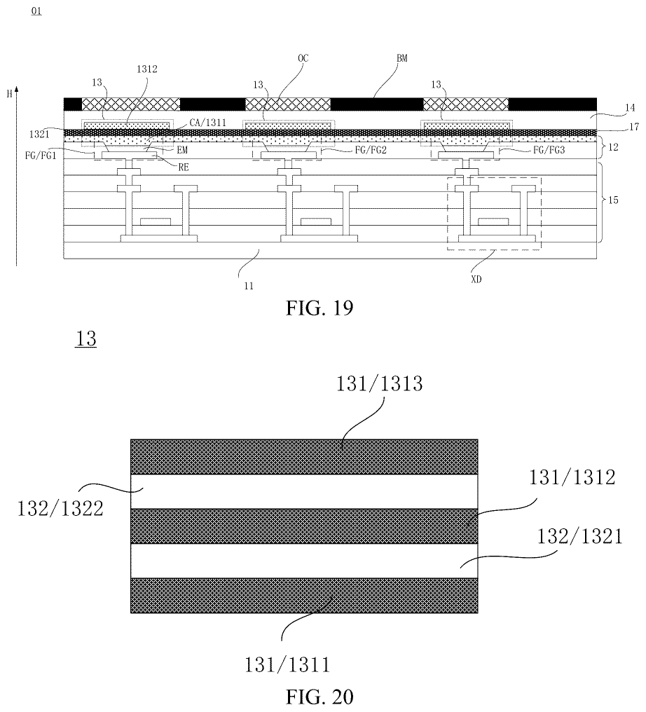

FIG. 19 is a schematic structural diagram of a further display panel according to an embodiment of the present disclosure.

In an embodiment of the present disclosure, as shown in FIG. 19, the light-emitting device FG includes a driving electrode RE, a light-emitting layer EM and a common electrode CA that are stacked. The light-emitting layer EM is located between the driving electrode RE and the common electrode CA, which is located at a side of the driving electrode RE away from the substrate 11. The driving electrode RE can be an anode of the light-emitting device FG, and the common electrode CA can be a cathode of the light-emitting device FG. Holes generated by the driving electrode RE and electrons generated by the common electrode CA meet in the light emitting layer EM to form excitons, thereby realizing the light emission of the light-emitting device FG.

The common electrode CA is reused as the first sub-metal layer 1311 of the anti-reflection layer 13.

In an example, the common electrode CA includes silver.

In the embodiments of the present disclosure, the common electrode CA is reused as the first sub-metal layer 1311 of the anti-reflection layer 13, so that when forming the anti-reflection layer 13, there is no need to repeatedly form the first sub-metal layer 1311. In this way, it facilitates simplifying the manufacture process of the display panel 01, and it reduces the number of film layers in the display panel 01, thereby realizing lightness and thinness of the display panel 01.

Still referring to FIG. 19, in an embodiment of the present disclosure, the display panel 01 further includes a first light extraction layer 17. The first light extraction layer 17 is disposed on the common electrode CA, and is configured to improve the light emission efficiency of the light-emitting device FG. The first light extraction layer 17 is reused as a first sub-dielectric layer 1321 of the anti-reflection layer 13.

It has been found through research that the first light extraction layer 17 is usually an organic layer or an inorganic layer, which meets the characteristic requirements of the dielectric layer 132 in the anti-reflection layer 13. In this embodiment, the first light extraction layer 17 is reused as the first sub-dielectric layer 1321 of the anti-reflection layer 13, so that when forming the anti-reflection layer 13, there is no need to repeatedly form the first sub-dielectric layer 1321. In this way, it is beneficial to further simplifying the manufacture process of the display panel 01, and it can further reduce the number of film layers in the display panel 01.

In an example, the first light extraction layer 17 is a cap layer CPL or a lithium fluoride layer LiF.

It should be noted that, in some other embodiments, the inorganic layer in the encapsulation layer 14 can be reused as the dielectric layer 132 of the anti-reflection layer 13. Since both the light-emitting device FG and the encapsulation layer 14 are of a multi-layer structure, when the anti-reflection layer 13 reuses the common electrode CA or the inorganic layer of the encapsulation layer 14, the anti-reflection layer 13 is located between the light-emitting device layer 12 and the encapsulation layer 14, meaning that the anti-reflection layer 13 is located between the light emitting layer EM of the light-emitting device FG and the outermost layer of the encapsulation layer 14, and the outermost layer of the encapsulation layer 14 refers to one of the plurality of film layers of the encapsulation layer 14 away from the substrate 11.

In an embodiment of the present disclosure, the first sub-metal layer 1311 and the second sub-metal layer 1312 in the anti-reflection layer 13 are made of a same material. For example, both of the first sub-metal layer 1311 and the second sub-metal layer 1312 include silver. In this way, the types of the material in the anti-reflection layer 13 can be reduced, thereby being beneficial to reducing the implementation difficulty of the anti-reflection layer 13.

In addition, in the anti-reflection layer 13, the first sub-metal layer 1311 and the second sub-metal layer 1312 can be made of different materials. For example, the first sub-metal layer 1311 includes silver, and the second sub-metal layer 1312 includes ytterbium. In this way, the structural diversity of the anti-reflection layer 13 can be increased, thereby improving the structural diversity of the display panel 01.

FIG. 20 is a schematic structural diagram of another anti-reflection layer according to an embodiment of the present disclosure.

In an embodiment of the present disclosure, as shown in FIG. 20, the metal layer 131 further includes a third sub-metal layer 1313 located at a side of the second sub-metal layer 1312 away from the first sub-metal layer 1311. The dielectric layer 132 further includes a second sub-dielectric layer 1322 located between the second sub-metal layer 1312 and the third sub-metal layer 1313.

That is, the anti-reflection layer 13 can include a first sub-metal layer 1311, a second sub-metal layer 1312, and a third sub-metal layer 1313 that are stacked. A first sub-dielectric layer 1321 is provided between the first sub-metal layer 1311 and the second sub-metal layer 1312, and a second sub-dielectric layer 1322 is provided between the second sub-metal layer 1312 and the third sub-metal layer 1313. The refractive index of the first sub-dielectric layer 1321 is greater than 1.3, and the refractive index the second sub-dielectric layer 1322 is greater than 1.3.

In this embodiment of the present disclosure, the anti-reflection layer 13 can include multiple interfaces between metal layer 131 and the dielectric layers 132, thereby facilitating formation of a plasmon effect at the multiple interfaces, thereby improving an effect that reflected light in the anti-reflection layer 13 can interfere to counteract, thereby further reducing an influence of reflection of the external ambient light on the display image.

In an example, the third sub-metal layer 1313 and the first sub-metal layer 1311 are made of a same material. Since the first sub-metal layer 1311 and the second sub-metal layer 1312 can be made of a same material, then in the anti-reflection layer 13, the materials of the first sub-metal layer 1311, the second sub-metal layer 1312 and the third sub-metal layer 1313 can all be the same, thereby being beneficial to reducing the types of materials in the anti-reflection layer 13, and reducing the implementation difficulty of the anti-reflection layer 13.

It should be noted that, in some other embodiments, the first sub-metal layer 1311, the second sub-metal layer 1312 and the third sub-metal layer 1313 can be made of materials that are different from each other; or two layers of the first sub-metal layer 1311, the second sub-metal layer 1312 and the third sub-metal layer 1313 can be made of a same material, and the remaining one layer of the first sub-metal layer 1311, the second sub-metal layer 1312 and the third sub-metal layer 1313 can be made of a material different from the material of those two layers.

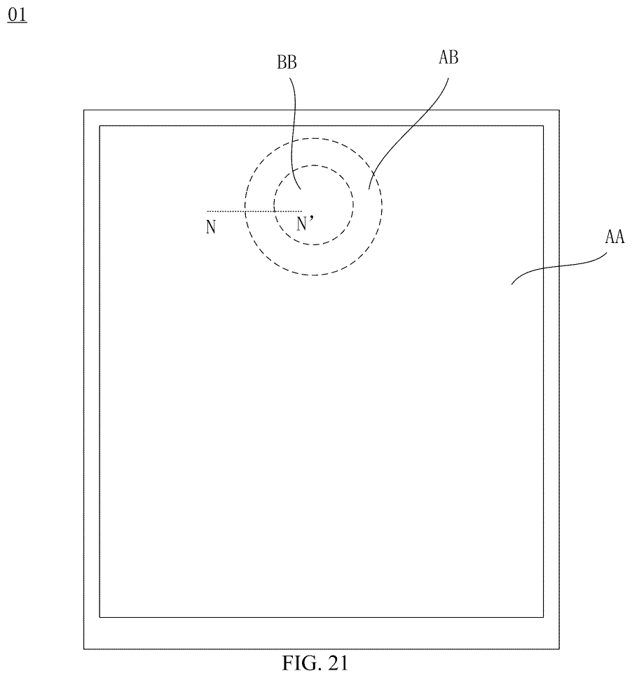

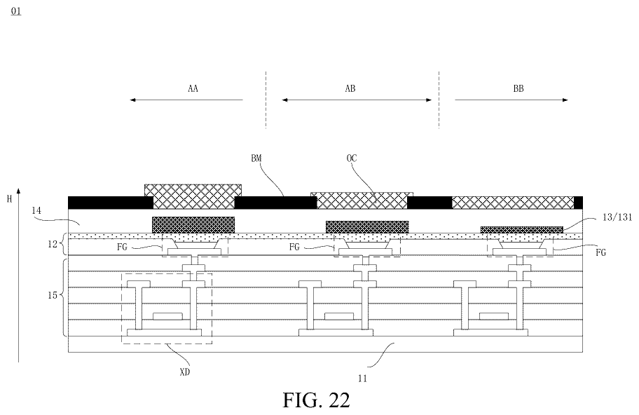

FIG. 21 is a schematic plan view of a display panel according to an embodiment of the present disclosure, and FIG. 22 is a schematic cross-sectional view along NN′ shown in FIG. 21.

In an embodiment of the present disclosure, as shown in FIG. 21, the display panel 01 includes a main display region AA, a light-transmission display region BB and a transition display region AB. The transition display region AB surrounds at least part of the light-transmission display region BB, the main display region AA surrounds at least part of the transition display region AB, and the transition display region AB is located between the main display region AA and the light-transmission display region BB. The light-transmission display region BB can be a display region corresponding to an under-screen optical component (such as a camera).

The transmittance of the light-transmission display region BB is greater than that of the transition display region AB, and the transmittance of the transition display region AB is greater than that of the main display region AA. That is, along a direction from the main display region AA towards the light-transmission display region BB, the light transmittance of the display panel 01 can gradually increase.

As shown in FIG. 22, along the direction from the main display region AA towards the light-transmission display region BB, a thickness of the metal layer 131 of the anti-reflection layer 13 gradually decreases.

That is, the thickness of the metal layer 131 of the anti-reflection layer 13 in the main display region AA is greater than that of the metal layer 131 of the anti-reflection layer 13 in the transition display region AB; and the thickness of the metal layer 131 of the anti-reflection layer 13 in the transition display region AB is greater than that of the metal layer 131 of the anti-reflection layer 13 in the light-transmission display region BB. Herein, the thickness of the metal layer 131 of the anti-reflection layer 13 refers to a total thickness of all the metal layers 131 of the anti-reflection layer 13.

It should be noted that, FIG. 22 merely illustrates the metal layer 131 of the anti-reflection layer 13, and a dielectric layer 132 is provided between adjacent sub-metal layers.

In the embodiments of the present disclosure, the light transmittance of the light-transmission display region BB is larger, thereby ensuring the lighting requirements of the under-screen optical component, and thus improving a working effect of the under-screen optical component. Moreover, the light transmittance of the transition display region AB is set to be greater than that of the main display region AA and less than that of the light-transmission display region BB, thereby avoiding a sudden change of the light transmittance in the display region of the display panel 01, and thus being beneficial to ensuring the display uniformity of the display panel 01.

In addition, in combination with the relationship between the thickness of the metal layer 131 and the light transmittance, the thickness of the metal layer 131 of the anti-reflection layer 13 in the light-transmission display region BB is set to be relatively small, which is beneficial to ensuring the larger light transmittance of the light-transmission display region BB, so as to meet the lighting requirements of the under-screen optical component. Meanwhile, along the direction from the main display region AA towards the light-transmission display region BB, the thickness of the metal layer 131 of the anti-reflection layer 13 gradually decreases. In this way, it can avoid an influence of a sudden change of the thickness of the metal layer 131 on the display image, thereby reducing a visual difference between the main display region AA and the light-transmission display region BB.

Further referring to FIG. 22, in an embodiment of the present disclosure, the display panel 01 further includes a reflection control layer OC. The thickness of the reflection control layer OC in the main display region AA is greater than that of the reflection control layer OC in the transition display region AB, and the thickness of the reflection control layer OC in the transition display region AB is greater than that of the reflection control layer OC in the light-transmission display region BB.

Further, along the direction from the main display region AA towards the light-transmission display region BB, the thickness of the reflection control layer OC gradually decreases.

In the embodiments of the present disclosure, the thickness of the reflection control layer OC in the light-transmission display region BB is smaller, which is beneficial to further ensuring that the light transmittance of the light-transmission display region BB is larger, thereby improving a working effect of the under-screen optical component. Moreover, an influence of a sudden change of the thickness of the reflection control layer OC on the display image can be avoided by setting the thickness of the reflection control layer OC to change gradually, thereby reducing a visual difference between the main display region AA and the light-transmission display region BB.

It should be noted that, when the color resist CF is provided in the display panel 01, the thickness of the color resist CF can be set to gradually decrease along the direction from the main display region AA towards the light-transmission display region BB.

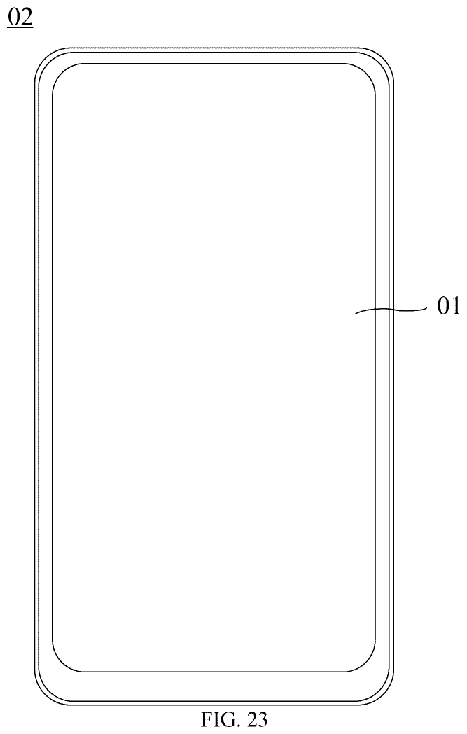

FIG. 23 is a schematic diagram of a display device according to an embodiment of the present disclosure.

As shown in FIG. 23, the embodiments of the present disclosure provide a display device 02, including the display panel 01 provided in the above-described embodiments. Exemplarily, the display device 02 may be an electronic device such as a computer, a television, a mobile phone, and a vehicle-mounted display, which will not be limited in the present disclosure.

In the display device 02, the anti-reflection layer 13 includes the first sub-metal layer 1311, the first sub-dielectric layer 1321, and the second sub-metal layer 1312 that are stacked, a plasmon effect can be formed at an interface between the first sub-metal layer 1311 and the first sub-dielectric layer 1321, and a plasmon effect can be formed at an interface between the second sub-metal layer 1312 and the first sub-dielectric layer 1321. When external ambient light enters the anti-reflection layer 13, the reflected light in a certain wave band reflected from the multiple interfaces of the anti-reflection layer 13 can interfere to counteract, thereby reducing transmission and reflection of external ambient light, and thus reducing an influence of reflection of external ambient light on the display image, and improving the display effect of the display panel 01.

In addition, the refractive index of the first sub-dielectric layer 1321 is set to be greater than 1.3, so that resonant tunneling can be formed in the anti-reflection layer 13, thereby allowing light within a specific wave band to pass through the anti-reflection layer 13, and thus ensuring that light emitted from the light-emitting device layer 12 can pass through the anti-reflection layer 13 and normally emit out, and avoiding that the anti-reflection layer 13 affects the display of the display panel 01.

The above-described embodiments are merely preferred embodiments of the present disclosure and are not intended to limit the present disclosure. Any modifications, equivalent substitutions and improvements made within the principle of the present disclosure shall fall into the protection scope of the present disclosure.

What is claimed is:

1. A display panel, comprising a light-emitting device layer, an anti-reflection layer and an encapsulation layer,
wherein the encapsulation layer is located at a side of the light-emitting device layer facing a light-exiting surface of the display panel, the anti-reflection layer is located between the light-emitting device layer and the encapsulation layer, and the anti-reflection layer is configured to reduce reflection of ambient light by the display panel; and
wherein the anti-reflection layer comprises a metal layer and a dielectric layer, the metal layer comprises a first sub-metal layer and a second sub-metal layer that are stacked, the dielectric layer comprises a first sub-dielectric layer located between the first sub-metal layer and the second sub-metal layer; and a refractive index of the dielectric layer is greater than 1.3.

2. The display panel according to claim 1,
wherein the light-emitting device layer comprises a plurality of light-emitting devices, which comprise a first-color light-emitting device, a second-color light-emitting device and a third-color light-emitting device; and
wherein in a thickness direction of the display panel, the anti-reflection layer overlaps with at least one of the first-color light-emitting device, the second-color light-emitting device, and the third-color light-emitting device; and the anti-reflection layer is configured to transmit light emitted by the light-emitting device that overlaps with the anti-reflection layer.

3. The display panel according to claim 2,
wherein in the thickness direction of the display panel, the anti-reflection layer overlaps with the first-color light-emitting device; and the anti-reflection layer is configured to transmit light emitted by the first-color light-emitting device.

4. The display panel according to claim 3, further comprising a color resist layer located at a side of the light-emitting device layer facing the light-exiting surface of the display panel,
wherein the color resist layer comprises a second-color resist and a third-color resist, and in the thickness direction of the display panel, the second-color resist overlaps with the second-color light-emitting device, and the third-color resist overlaps with the third-color light-emitting device.

5. The display panel according to claim 3, further comprising a reflection control layer,
wherein the reflection control layer is located at a side of the light-emitting device layer facing the light-exiting surface of the display panel; and
wherein in the thickness direction of the display panel, the reflection control layer overlaps with each of the second-color light-emitting device and the third-color light-emitting device, and the reflection control layer is configured to transmit light emitted by the second-color light-emitting device and light emitted by the third-color light-emitting device.

6. The display panel according to claim 2,
wherein in the thickness direction of the display panel, the anti-reflection layer overlaps with each of the first-color light-emitting device and the second-color light-emitting device, and the anti-reflection layer is configured to transmit light emitted by the first-color light-emitting device and light emitted by the second-color light-emitting device.

7. The display panel according to claim 6, further comprising a color resist layer located at a side of the light-emitting device layer facing the light-exiting surface of the display panel,
wherein the color resist layer comprises a third-color resist which overlaps with the third-color light-emitting device in the thickness direction of the display panel.

8. The display panel according to claim 6, further comprising a reflection control layer located at a side of the light-emitting device layer facing the light-exiting surface of the display panel,
wherein in the thickness direction of the display panel, the reflection control layer overlaps with the third-color light-emitting device, and is configured to transmit light emitted by the third-color light-emitting device.

9. The display panel according to claim 2,
wherein the anti-reflection layer overlaps with each of the first-color light-emitting device, the second-color light-emitting device, and the third-color light-emitting device in the thickness direction of the display panel; and the anti-reflection layer is configured to transmit light emitted by the first-color light-emitting device, light emitted by the second-color light-emitting device, and light emitted by the third-color light-emitting device.

10. The display panel according to claim 2,
wherein the anti-reflection layer comprises a first-type anti-reflection layer, a second-type anti-reflection layer and a third-type anti-reflection layer; and in the thickness direction of the display panel, the first-type anti-reflection layer overlaps with the first-color light-emitting device, the second-type anti-reflection layer overlaps with the second-color light-emitting device, and the third-type anti-reflection layer overlaps with the third-color light-emitting device; and
wherein the first-type anti-reflection layer is configured to transmit light emitted by the first-color light-emitting device, the second-type anti-reflection layer is configured to transmit light emitted by the second-color light-emitting device, and the third-type anti-reflection layer is configured to transmit light emitted by the third-color light-emitting device.

11. The display panel according to claim 9, further comprising a reflection control layer,
wherein the reflection control layer is located at a side of the anti-reflection layer facing the light-exiting surface of the display panel, and light transmittance of the reflection control layer ranges from 40% to 70%.

12. The display panel according to claim 10, further comprising a reflection control layer,
wherein the reflection control layer is located at a side of the anti-reflection layer facing the light-exiting surface of the display panel, and light transmittance of the reflection control layer ranges from 40% to 70%.

13. The display panel according to claim 1,
wherein the metal layer comprises at least one of silver, gold, copper, cobalt, nickel, ytterbium, bismuth, titanium, tungsten, or molybdenum.

14. The display panel according to claim 1,
wherein the first sub-metal layer and the second sub-metal layer are made of a same material.

15. The display panel according to claim 1,
wherein the metal layer further comprises a third sub-metal layer located at a side of the second sub-metal layer away from the first sub-metal layer; and the dielectric layer further comprises a second sub-dielectric layer located between the second sub-metal layer and the third sub-metal layer.

16. The display panel according to claim 15, wherein the third sub-metal layer and the first sub-metal layer are made of a same material.

17. The display panel according to claim 2,
wherein the light-emitting device comprises a driving electrode, a light-emitting layer and a common electrode that are stacked, and the common electrode is reused as the first sub-metal layer of the anti-reflection layer.

18. The display panel according to claim 17, further comprising a first light extraction layer, wherein the first light extraction layer is disposed on the common electrode, and is reused as a first sub-dielectric layer of the anti-reflection layer.

19. The display panel according to claim 1,
wherein the display panel comprises a main display region, a light-transmission display region and a transition display region, wherein the transition display region surrounds at least part of the light-transmission display region, and the main display region surrounds at least part of the transition display region,
wherein light transmittance of the light-transmission display region is greater than light transmittance of the transition display region, and the light transmittance of the transition display region is greater than light transmittance of the main display region; and
wherein a thickness of the metal layer of the anti-reflection layer decreases along a direction from the main display region towards the light-transmission display region.

20. A display device, comprising a display panel comprising a light-emitting device layer, an anti-reflection layer and an encapsulation layer,
wherein the encapsulation layer is located at a side of the light-emitting device layer facing a light-exiting surface of the display panel, the anti-reflection layer is located between the light-emitting device layer and the encapsulation layer, and the anti-reflection layer is configured to reduce reflection of ambient light by the display panel; and
wherein the anti-reflection layer comprises a metal layer and a dielectric layer, the metal layer comprises a first sub-metal layer and a second sub-metal layer that are stacked, the dielectric layer comprises a first sub-dielectric layer located between the first sub-metal layer and the second sub-metal layer; and a refractive index of the dielectric layer is greater than 1.3.
